(19) United States
(12) Patent Application Publication
(10) Pub. No.: US 2007/0063339 A1
(43) Pub. Date: Mar. 22, 2007

(54) Heat dissipating assembly for heat dissipating substrate and application

(75) Inventor: Pei-Chih Yao, Taipei (TW)

Correspondence Address: BACON & THOMAS, PLLC, 625 SLATERS LANE, FOURTH FLOOR, ALEXANDRIA, VA, 22314, US

(73) Assignee: GRAND POWER SOURCES INC., TAIPEI (TW)

(21) Appl. No.: 11/230,651

(22) Filed: Sep. 21, 2005

(51) Int. Cl. H01L 23/34

(52) U.S. Cl. 257/720

(57) ABSTRACT

In a heat dissipating assembly for heat dissipating substrate and application, a heat dissipating substrate is made of a graphite layer and a thermal conductive metal layer covered onto the surface of the graphite layer, so that when the heat dissipating substrate is placed on a heat source, the graphite in a specific direction has a thermal conductivity faster than general thermal conductive metal materials, and the graphite layer can quickly conduct the heat produced by the heat source. Since the heat conduction of the graphite is anisotropic, therefore the graphite layer of the invention can quickly conduct heat and also can improve the structural strength of the metal layer and facilitate the formation, and heat can be dissipated to the outside by the isotropic thermal conductivity property. The heat dissipating substrate can be stamped to form a plurality of penetrating cavities or semi-protruded holes, and these semi-protruded holes have a specific inclination for increasing the surface area and quickly dissipating heat, and their arranged direction and the size of the stamped holes can change the direction of the cooling air, so as to enhance the cooling effect.

### BACKGROUND OF THE INVENTION

1. Field of the Invention

The present invention relates to a heat dissipating assembly for heat dissipating substrate and application, and more particularly to a heat dissipating assembly for heat dissipating substrate and application that uses a compound substrate comprised of a graphite layer and a thermal conductive metal for quickly dissipating the heat of a heat source.

2. Description of the Related Art

In recent years, the development of electronic products including LSI, digital camera, mobile phone, and notebook computers tends to be densely packaged and multifunctional, which makes the heat dissipation very difficult. If the electronic components do not have a proper heat dissipating policy, the performance cannot be maximized, or more seriously the electronic products are unable due to the drastic increase of heat in the machine.

To suppress the rise of the temperature of the electronic components in an electronic product, a high thermal conductive metal heat sink made of copper or aluminum is used for dissipating the heat produced by the electronic components from the surface according to the temperature difference of the heat and the external air.

Regardless of the metal heat sink modules, the volume of the heat sink will be increased as the area of the electronic components and the speed of producing heat are increased. However, an increase of volume will increase the weight. More particularly, electronic products tend to be light, thin, short, and compact, and it is obvious that the internal space provided by electronic products for dissipating heat is insufficient. The increase in weight of the heat sink may press and damage the electronic components or have other adverse effects.

### SUMMARY OF THE INVENTION

In view of the foregoing shortcomings of the prior art metal heat spreader, the inventor of the present invention based on years of experience to conduct extensive researches and finally invented the heat dissipating assembly for heat dissipating substrate and application in accordance with the present invention.

Therefore, it is a primary objective of the present invention to provide a heat dissipating substrate, and the heat dissipating substrate comprises a graphite layer and a thermal conductive metal layer covered onto the surface of the graphite layer, so that when a cross-section with a quick thermal conduction is attached onto the heat source, the graphite is lightweight and has a thermal conductivity better than the general thermal conductive metal material in a specific direction, such that the graphite layer can quickly conduct the heat produced by the heat source. Since the thermal conductivity of the graphite is anisotropic, therefore the isotropic thermal conductive metal layer covered onto the graphite layer conducts the heat towards other directions and dissipates to the outside quickly. In the meantime, the metal layer has the property of a convenient formation and an enhanced structural strength. Therefore, the invention not only has a lighter weight, a smaller volume, and a higher thermal conductivity than the prior art heat dissipating metal plate, without the limitation of the shape and area.

Another objective of the present invention is to provide a heat dissipating assembly using a heat dissipating substrate, and the heat dissipating substrate comprises a graphite layer and a thermal conductive metal layer, and the heat dissipating substrate comprises a plurality of semi-protruded holes stamped from the heat dissipating substrate, and the semi-protruded holes have a specific inclination. Therefore, when the heat dissipating assembly is in use, the heat dissipating area is increased and the heat dissipating effect is faster. The cool air blown from the fan flows along the extended direction of the semi-protruded hole to extend the stagnant time and improve the cooling effect.

A further objective of the present invention is to provide a heat dissipating assembly using a heat dissipating substrate, and the heat dissipating substrate comprises a graphite layer and a thermal conductive metal layer, and the heat dissipating substrate comprises a plurality of penetrating cavities stamped from the heat dissipating substrate, such that the design of the cavity carries away the heat from the edges of the graphite and metal layer when the airflow passes through the internal edge of the cavity, and thus increasing the heat dissipating area and improving the cooling effect.

Another objective of the present invention is to provide a heat dissipating assembly using a heat dissipating substrate, and the heat dissipating substrate comprises a graphite layer and a thermal conductive metal layer, and the heat dissipating substrate comprises a plurality of cavities stamped from the heat dissipating substrate, and the isotropic thermal conductivity material is attached closely to the heat source, and the isotropic thermal conductivity material includes a protruded point corresponding to the cavity disposed on the heat dissipating substrate, such that the protruded point is in a close contact with a cross-section of the cavity on the heat dissipating substrate having a high thermal conductivity to carry away the heat quickly, and thus increasing the heat dissipating area and improving the cooling effect.

Another objective of the present invention is to provide a heat dissipating assembly using a heat dissipating substrate, and the heat dissipating substrate comprises a graphite layer and a thermal conductive metal layer, and the heat dissipating substrate includes a cavity disposed thereon, and the cavity is attached closely onto an isotropic thermal conductive base on the heat source, and the base includes a hole groove corresponding to the cavity on the heat dissipating substrate, and the cavity for receiving the metal pillar on the heat dissipating substrate is coupled closely with the hole groove by a rivet to quickly carry away the heat, and thus increasing the heat dissipating area and improving the cooling effect.

Another further objective of the present invention is to provide a heat dissipating assembly using a heat dissipating substrate comprising a base, and the base is a stairway shaped member with decreased areas in sequence, and both sides of the stairway shaped member are in a close contact with the cross-section of the heat dissipating substrate of the curved body having a high thermal conductivity, and the curved body can be used for conducting a hot flow, such that when the hot flow flows along the extending direction of the semi-protruded hole of the heat dissipating substrate or the internal edge of the cavity, the cooling effect can be improved due to the increase of heat dissipating area.

### BRIEF DESCRIPTION OF THE DRAWINGS

To make it easier for our examiner to understand the objective of the invention, the structure, innovative features and performance of the heat dissipating structure for a heat dissipating substrate and application of the invention, we use the following preferred embodiments with the attached drawings for the detailed description of the invention.

FIG. 1 is a cross-sectional view of a heat dissipating substrate according to a preferred embodiment of the present invention;

FIG. 1a is a cross-sectional view of a heat dissipating substrate according to another preferred embodiment of the present invention;

FIG. 1b is a cross-sectional view of a heat dissipating substrate according to a further preferred embodiment of the present invention;

FIG. 2 is a schematic view of a heat dissipating structure according to a first preferred embodiment of the present invention;

FIG. 2a is a schematic view of a heat dissipating structure according to a second preferred embodiment of the present invention;

FIG. 3 is a schematic view of a heat dissipating structure according to a third preferred embodiment of the present invention;

FIG. 3a is a schematic view of a heat dissipating structure according to a fourth preferred embodiment of the present invention;

FIG. 3b is a schematic view of a heat dissipating structure according to a fifth preferred embodiment of the present invention;

FIG. 4 is a schematic view of a heat dissipating structure according to a sixth preferred embodiment of the present invention;

FIG. 4a is a schematic view of a heat dissipating structure according to a seventh preferred embodiment of the present invention;

FIG. 5 is a schematic view of a heat dissipating structure according to an eighth preferred embodiment of the present invention;

FIG. 5a is a schematic view of a heat dissipating structure according to a ninth preferred embodiment of the present invention;

FIG. 6 is a schematic view of a heat dissipating structure according to a tenth preferred embodiment of the present invention;

FIG. 6a is a schematic view of a heat dissipating structure according to an eleventh preferred embodiment of the present invention;

FIG. 7 is a schematic view of a heat dissipating structure according to a twelfth preferred embodiment of the present invention;

FIG. 7a is a schematic view of a heat dissipating structure according to a thirteenth preferred embodiment of the present invention;

FIG. 8 is a schematic view of a heat dissipating structure according to a fourteenth preferred embodiment of the present invention;

FIG. 9 is a schematic view of a heat dissipating structure according to a fifteenth preferred embodiment of the present invention; and

FIG. 9a is a schematic view of a heat dissipating structure according to a sixteenth preferred embodiment of the present invention.

### DETAILED DESCRIPTION OF THE PREFERRED EMBODIMENTS

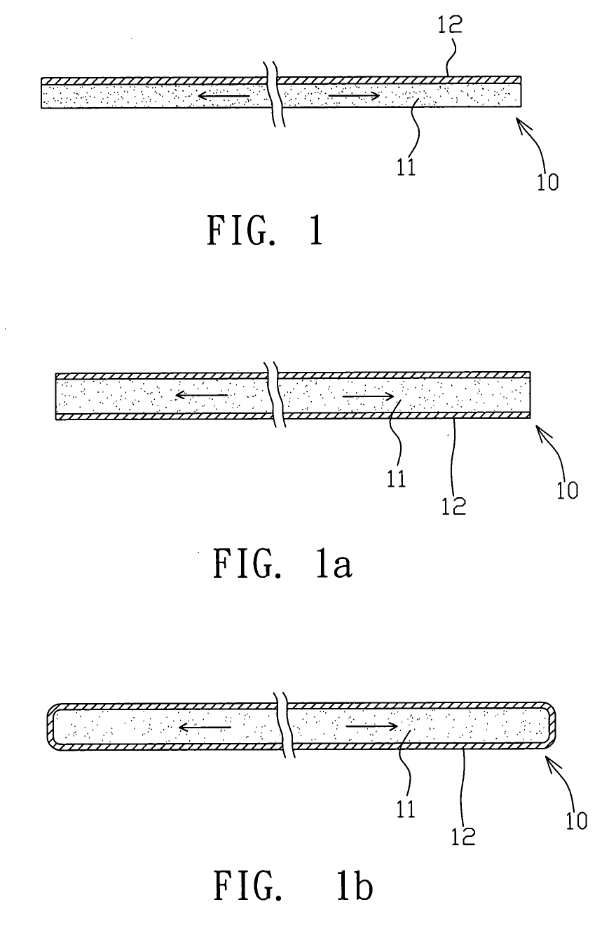

Referring to FIGS. 1, 1a and 1b for the heat dissipating substrate according to a preferred embodiment of the present invention, the heat dissipating substrate 10 comprises a graphite layer 11 which is a slab in this embodiment, and the thickness of the graphite layer 11 varies as needed, and the graphite layer 11 is covered by at least one thermal conductive metal layer 12 (as shown in FIG. 1) which could be a thermal conductive metal including copper, aluminum, and nickel alloy, and the thermal conductive metal layer 12 can be covered on both the upper and lower sides of the graphite layer 11 (as shown in FIG. 1a) or the thermal conductive metal layer 12 can be fully covered onto the periphery of the graphite layer 11 (as shown in FIG. 1b), and the graphite layer 11 can be coupled closely with the thermal conductive metal layer 12 by gluing.

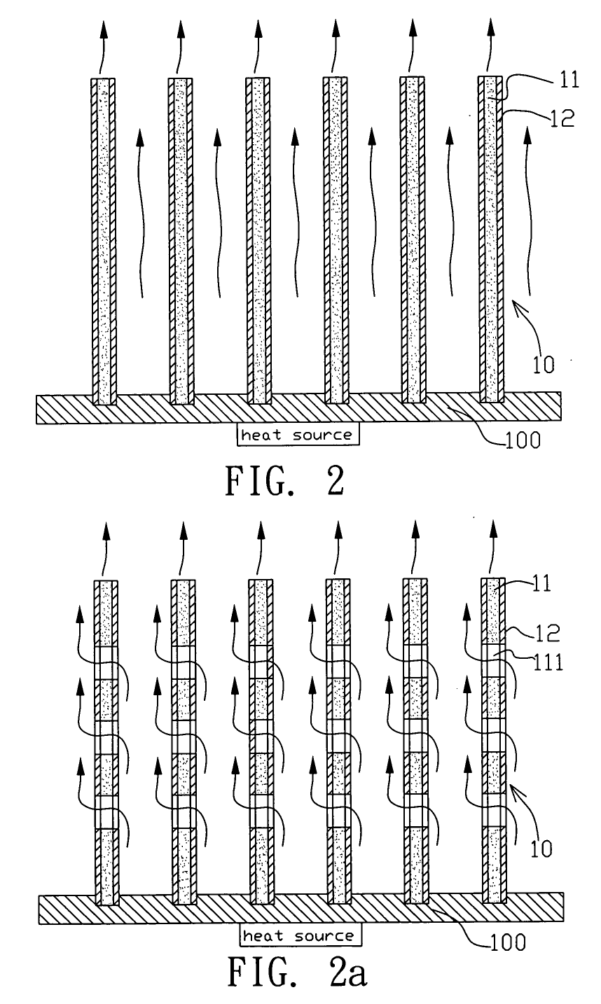

When the heat dissipating substrate 10 is placed onto a heat source of the electronic product as shown in FIGS. 2 and 2a, the graphite is lightweight and has a quick thermal conductivity in a specific direction, and thus the cross-section of the heat dissipating substrate 10 is placed onto the base 100 of the isotropic high thermal conductivity, and the base 100 is attached closely onto the heat source, such that the graphite layer 11 can conduct the heat produced by the heat source quickly. Since the thermal conduction of the graphite is anisotropic and the graphite of this embodiment has a high thermal conductivity in the direction vertical to the heat source and a less thermal conductivity along the horizontal direction, therefore when conducting heat, the graphite layer 11 combines the isotropic thermal conductivity of the metal layer 12 to dissipate the heat to the outside from different directions. This embodiment not only comes with a weight lighter than the prior art heat dissipating metal plate, but also provides a faster thermal conduction.

The heat dissipating substrate 10 can be used to develop the following heat dissipating assemblies. Referring to FIGS. 2 and 2a for the first and second preferred embodiments of the present invention respectively, the assembly comprises a base 100, and the base 100 is made of an isotropic high thermal conductivity material, and the base 100 comprises a plurality of vertical heat dissipating substrates 10 embedded into the base 100, and the heat dissipating substrate 10 is comprised of a graphite layer 11 and a thermal conductive metal layer 12, and the heat dissipating substrate 10 includes a cavity 111 thereon (as shown in FIG. 2a), such that when the heat dissipating assembly is in use, the base 100 absorbs a heat source quickly and then uses graphite having a high thermal conductivity along the direction perpendicular to the heat source and a less thermal conductivity along the horizontal direction and combines the isotropic thermal conductivity of the thermal conductive metal layer 12 to dissipate the heat in different directions to the outside quickly, as well as increasing the heat dissipating area of the cavity 111 and changing the airflow direction.

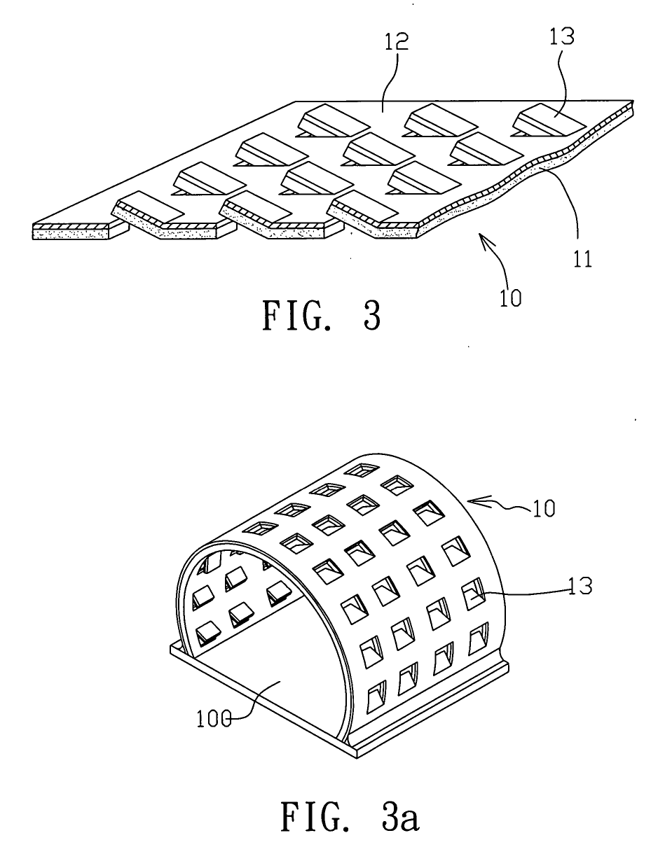

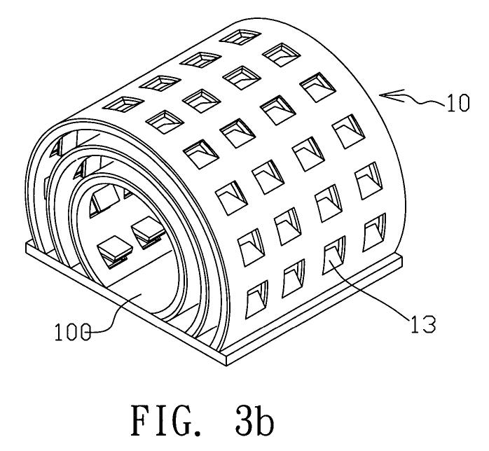

Referring to FIG. 3 for the third preferred embodiment of the present invention, the assembly comprises a heat dissipating substrate 10, and the heat dissipating substrate 10 comprises a semi-protruded hole 13 stamped from the heat dissipating substrate 10, and the semi-protruded hole 13 is integrally coupled to the heat dissipating substrate 10, and the semi-protruded hole 13 can be extended inward or outward, so that the extension of the semi-protruded hole 13 not only increases the heat dissipating area, but also changes the airflow direction of the external air or a fan, and thus increasing the stagnant time and improving the cooling effect.

Referring to FIGS. 3a and 3b for the fourth and fifth preferred embodiments of the present invention respectively, the foregoing heat dissipating substrate 10 can be bent into an arch shape, and the cross-section of the heat dissipating substrate 10 having a high thermal conductivity is fixed onto an isotropic high thermal conductivity base 100, and the heat dissipating substrate 10 is fixed onto the base 100 with one layer or a plurality of layers stacked with each other. Therefore, the base 100 quickly absorbs the heat source and uses the extension of the semi-protruded hole 13 to increase the heat dissipating area and changes the airflow direction of the outside air or a fan, and thus increasing the stagnant time and improving the cooling effect.

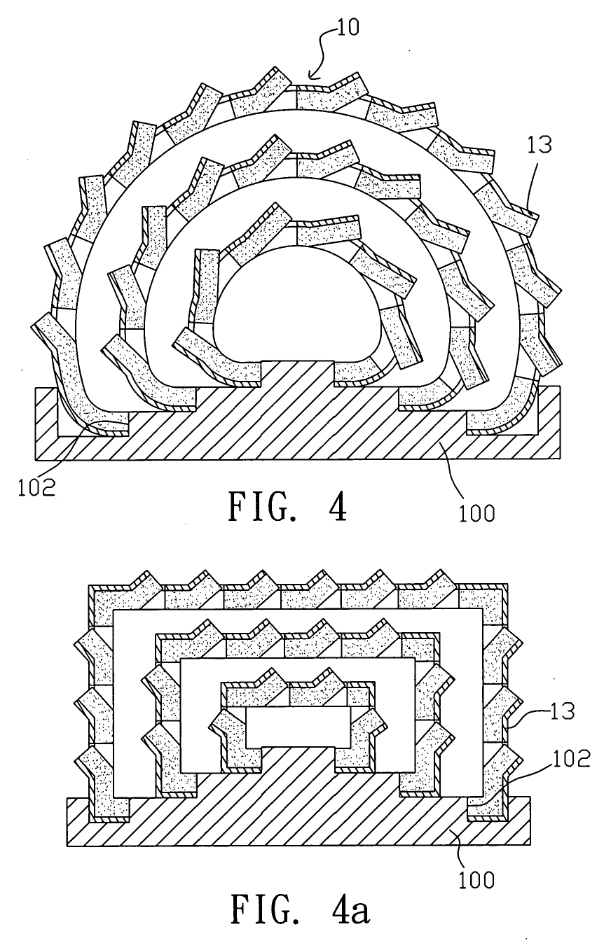

Referring to FIGS. 4 and 4a for the sixth and seventh preferred embodiments of the present invention respectively, the foregoing heat dissipating substrate 10 can be bent into an arch shape or a rectangular shape and fixed onto the base 100, and the heat dissipating substrate 10 can be fixed onto the base 100 with a plurality of layers stacked with each other, and the base 100 is made of an isotropic high thermal conductivity material, and the base 100 includes a stairway shaped member 102 for fixing the cross-section of each layer of the heat dissipating substrate 10 having a high thermal conductivity. The base 100 quickly absorbs the heat source and uses the extension of the semi-protruded hole 13 to increase the heat dissipating area and changes the airflow direction of the outside air or a fan, and thus increasing the stagnant time and improving the cooling effect.

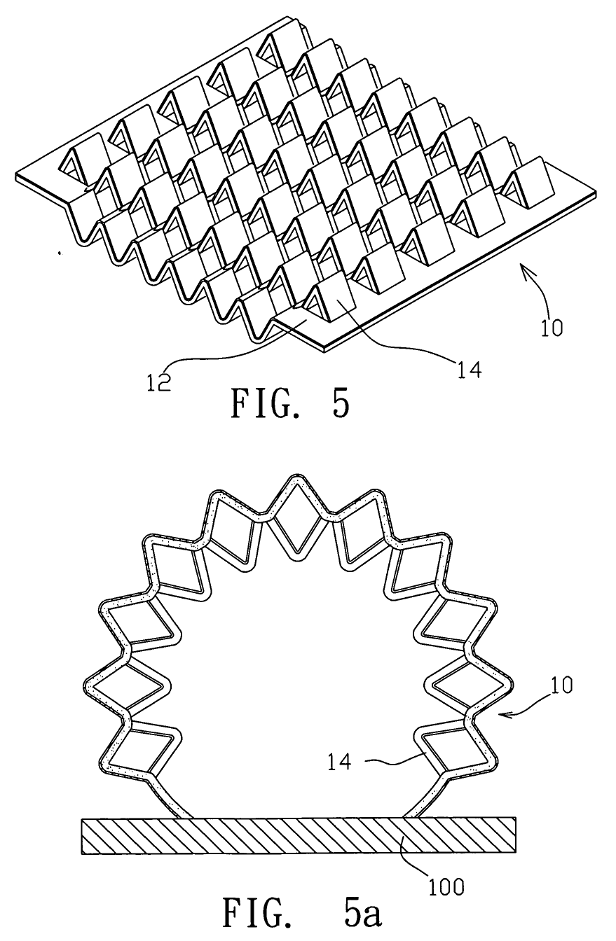

Referring to FIGS. 5 and 5a for the eighth and ninth preferred embodiments of the present invention respectively, the assembly comprises a heat dissipating substrate 10, and the heat dissipating substrate 10 comprises a plurality of wavy protrusions 14, and these protrusions 14 are hollow in shape. Therefore, the extension of the protrusions 14 not only increases the heat dissipating area of the graphite layer and the metal layer, but also changes the airflow direction of the outside air or a fan by the hollow protrusions 14, and thus increasing the stagnant time and improving the cooling effect. The heat dissipating substrate 10 could be bent into an arc shape, and the cross-section of the heat dissipating substrate 10 having a high thermal conductivity is embedded onto the base 100, and the base 100 is made of an isotropic high thermal conductivity material for absorbing the heat dissipated by the heat source (as shown in FIG. 5a).

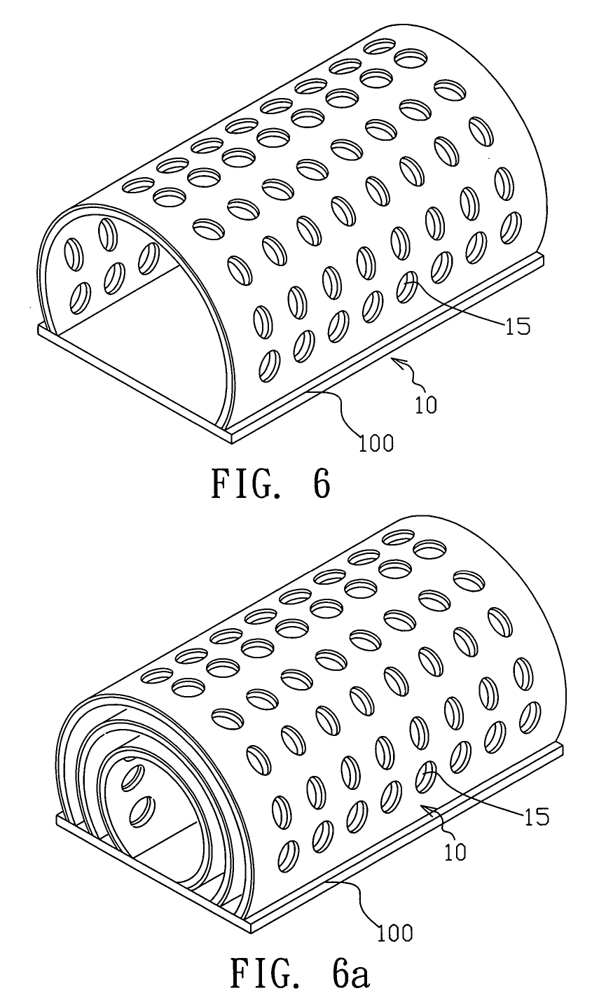

Referring to FIGS. 6 and 6a for the tenth and eleventh preferred embodiments of the present invention respectively, the assembly comprises an isotropic high thermal conductivity base 100, and the base 100 is installed onto the heat source of an electronic product, and the base 100 is connected with the cross-section of the heat dissipating substrate 10 having a high thermal conductivity. This embodiment could be one layer or three layers, and the heat dissipating substrate 10 comprises a plurality of stamped holes 15 stamped from the heat dissipating substrate 10, and these stamped hole 15 constitute a penetrating cavity. These stamped holes 15 allows the airflow passing through the cavity to quickly carry away the heat at the metal edges and the graphite, and thus increasing the heat dissipating area and improving the cooling effect.

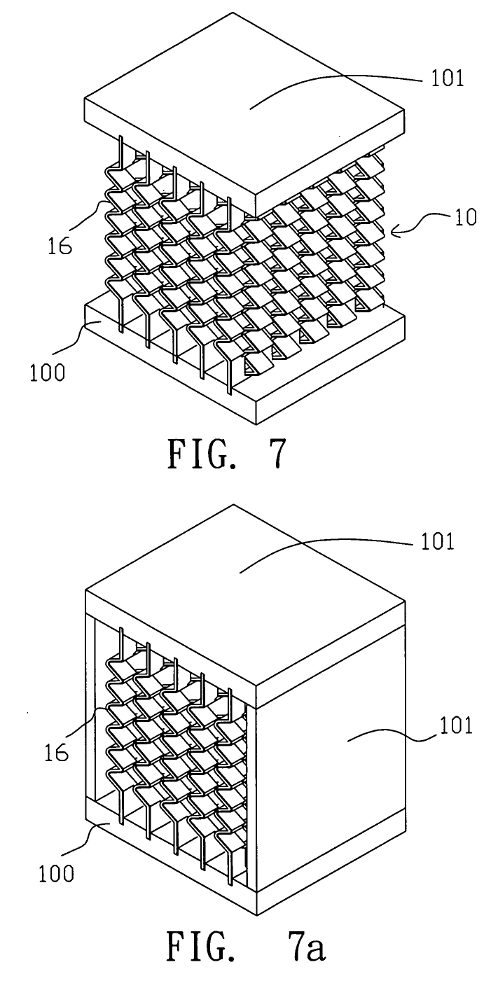

Referring to FIGS. 7 and 7a for the twelfth and thirteenth preferred embodiments of the present invention respectively, the assembly comprises a high thermal conductivity base 100, and the base 100 is installed onto the heat source of an electronic product, and the base 100 is closely connected to a cross-section of the heat dissipating substrate 10 having a high thermal conductivity and perpendicular to the heat source, and the heat dissipating substrate 10 comprises a plurality of wavy protrusions 16, and a cover body 101 is embedded onto the periphery of the base 100 or a corresponding end for fixing the heat dissipating substrate 10 and creating an air passage. Therefore, the extension of the heat dissipating substrate 10 not only increases the heat dissipating area, but also uses the extending direction of the protrusions 16 to change the airflow direction of the outside air or a fan, and thus increasing the stagnant time and improving the cooling effect.

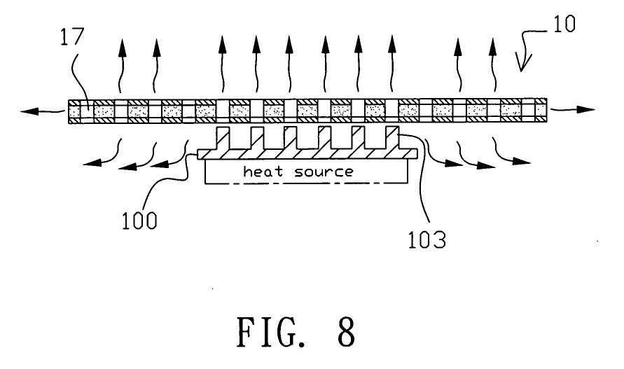

Referring to FIG. 8 for the fourteenth preferred embodiment of the present invention, the heat dissipating substrate 10 with the stamped holes 15 are attached onto the isotropic high thermal conductivity base 100, which is attached onto a heat source. The high thermal conductivity base 100 comprises a protruded point 103 corresponding to the stamped cavity 17 on the heat dissipating substrate 10, so that the protruded point 103 is in a close contact with the stamped cavity 17 of the heat dissipating substrate 10 to carry away the heat, and thus increasing the heat dissipating area and improving the cooling effect.

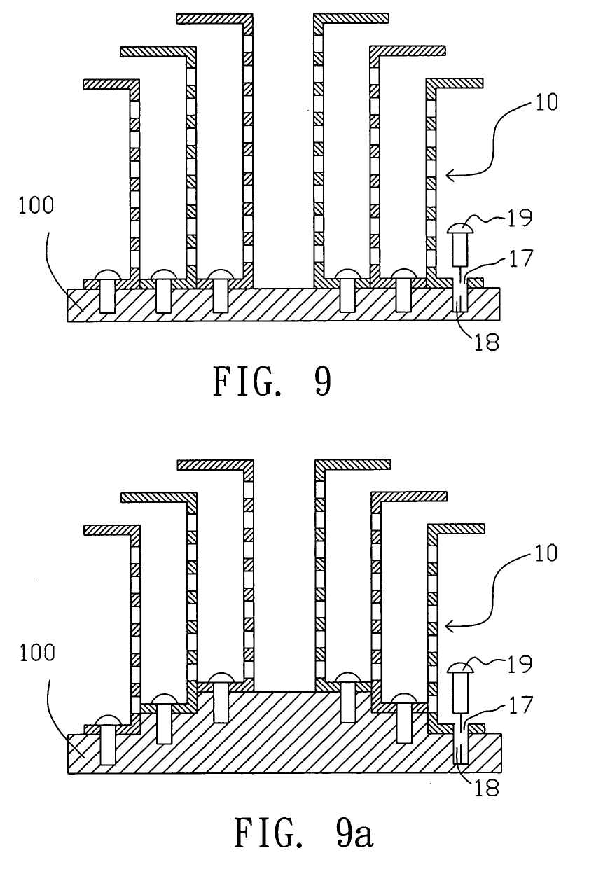

Referring to FIGS. 9 and 9a for the fifteenth and sixteenth preferred embodiments of the present invention respectively, the heat dissipating substrate 10 with the stamped holes is attached onto an isotropic high thermal conductivity base 100 of the heat source, and the heat dissipating substrate 10 comprises a stamped cavity 17, and the base 100 corresponding to the stamped cavity 17 comprises a corresponding hole groove 18, and a high thermal conductivity metal pillar 19 passes through the stamped cavity 17 and is fixed into the hole groove 18 on the base 100 by a rivet. Therefore, the metal pillar 19 is in a close contact with the stamped cavity 17 on the heat dissipating substrate 10 to carry away the heat quickly, and thus increasing the heat dissipating area and improving the cooling effect.

The foregoing base 100 could be made of an aluminum alloy, a copper alloy, a nickel alloy, graphite or metal compounds.

In summation of the above description, the present invention herein complies with the patent application requirements and is submitted for patent application. However, the description and its accompanied drawings are used for describing preferred embodiments of the present invention, and it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A heat dissipating substrate, comprising:
a graphite layer; and
a thermal conductive metal layer, being covered onto the surface of said graphite layer, and said thermal conductive metal layer is coupled closely with said graphite layer;
thereby when said heat dissipating substrate is placed on a heat source, a cross section of said heat dissipating substrate having a quick thermal conduction property in a specific direction is attached closely on said heat source, since the graphite is lightweight, and the heat produced by said heat source can be conducted quickly by said graphite layer, and since the thermal conduction of graphite is anisotropic, therefore the thermal conduction of said graphite layer can be dissipated quickly to the outside from said metal layer without being limited by directions, and thus said heat dissipating substrate has a weight lighter than a prior art heat dissipating metal plate, and also provides a fast thermal conduction without being limited by the area and direction.

2. The heat dissipating substrate of claim 1, wherein said thermal conductive metal layer is covered onto a single side of said graphite layer.

3. The heat dissipating substrate of claim 1, wherein said thermal conductive metal layer is covered onto double sides of said graphite layer.

4. The heat dissipating substrate of claim 1, wherein said thermal conductive metal layer is covered onto the periphery of said graphite layer.

5. The heat dissipating substrate of claim 1, wherein said thermal conductive metal layer is made of an aluminum alloy.

6. The heat dissipating substrate of claim 1, wherein said thermal conductive metal layer is made of a copper alloy.

7. The heat dissipating substrate of claim 1, wherein said thermal conductive metal layer is made of a nickel alloy.

8. A heat dissipating assembly using a heat dissipating substrate, said assembly comprising:
a base, being made of an isotropic thermal conductive material; and
a heat dissipating substrate, being vertically embedded into said base and comprised of a graphite layer and a thermal conductive metal layer;
thereby when said heat dissipating assembly is in use, said base quickly absorbs a heat source and dissipates the heat from different directions to the outside by a graphite having a high thermal conductivity in the direction perpendicular to said heat source and a less thermal conductivity along the horizontal direction together with the isotropic thermal conductivity.

9. The heat dissipating assembly using a heat dissipating substrate of claim 8, wherein said heat dissipating substrate comprises a cavity stamped from said heat dissipating substrate.

10. A heat dissipating assembly using a heat dissipating substrate, said heat dissipating substrate comprising a graphite layer and a thermal conductive metal layer, and said heat dissipating substrate comprises a semi-protruded holes stamped from said heat dissipating substrate, and said semi-protruded hole and said heat dissipating substrate are integrally coupled, such that said semi-protruded hole is extended to improve the heat dissipating area and change the airflow direction of the outside air or a fan, so as to increase the stagnant time and improve the cooling effect.

11. The heat dissipating assembly using a heat dissipating substrate of claim 10, wherein said semi-protruded hole is extended inward.

12. The heat dissipating assembly using a heat dissipating substrate of claim 10, wherein said semi-protruded hole is extended outward.

13. The heat dissipating assembly using a heat dissipating substrate of claim 10, wherein said heat dissipating substrate is fixed onto a base in an arch shape, and said base is made of an isotropic high thermal conductivity material.

14. The heat dissipating assembly using a heat dissipating substrate of claim 10, wherein said heat dissipating substrate is fixed onto a base in an arch shape, and said base is made of an isotropic high thermal conductivity material.

15. The heat dissipating assembly using a heat dissipating substrate of claims 13 or 14, wherein said heat dissipating substrate comprises a plurality of layers.

16. The heat dissipating assembly using a heat dissipating substrate of claims 13 or 14, wherein said base is a stairway-shape base.

17. A heat dissipating assembly using a heat dissipating substrate, said heat dissipating substrate comprising a graphite layer and a thermal conductive metal layer, and said heat dissipating substrate comprising a plurality of wavy protrusions stamped from said heat dissipating substrate, and said protrusions are hollow such that said protrusions are extended to increase the heat dissipating area and change the airflow direction of the outside air or a fan by a part of said protrusions, so as to increase the stagnant time and improve the cooling effect.

18. The heat dissipating assembly using a heat dissipating substrate of claim 17, wherein said heat dissipating substrate is bent and fixed onto a base, and said base is made of an isotropic high thermal conductivity material.

19. The heat dissipating assembly using a heat dissipating substrate of claim 18, wherein said heat dissipating substrate is substantially in an arch shape.

20. The heat dissipating assembly using a heat dissipating substrate of claim 18, wherein said heat dissipating substrate is substantially in a rectangular shape.

21. The heat dissipating assembly using a heat dissipating substrate of claim 18, wherein said heat dissipating substrate comprises a plurality of layers.

22. The heat dissipating assembly using a heat dissipating substrate of claim 18, wherein said base is a stairway shaped base.

23. A heat dissipating assembly using a heat dissipating substrate, comprising a base, and said base comprises a plurality of wavy bent vertical embedded members, and said embedded member comprises a graphite layer and a thermal conductive metal layer, such that said embedded members are extended to increase the heat dissipating area and change the airflow direction of the outside air or a fan by the extended direction of said embedded members to increase the stagnant time and improve the cooling effect.

24. The heat dissipating assembly using a heat dissipating substrate of claim 23, wherein said embedded member includes a cover body disposed at an end not coupled to said base.

25. The heat dissipating assembly using a heat dissipating substrate of claim 23, wherein said embedded member includes a cover body disposed at an end or both ends not coupled to said base.

26. A heat dissipating assembly using a heat dissipating substrate, including a base comprised of a graphite layer and a thermal conductive metal layer, and said base includes at least one heat dissipating substrate, and said heat dissipating substrate includes a cavity stamped from said heat dissipating substrate, and said cavity is a penetrating cavity.

27. The heat dissipating assembly using a heat dissipating substrate of claim 26, wherein said heat dissipating substrate is in an arch shape.

28. The heat dissipating assembly using a heat dissipating substrate of claim 26, wherein said heat dissipating substrate is in a rectangular shape.

29. The heat dissipating assembly using a heat dissipating substrate of claim 26, wherein said heat dissipating substrate comprises a plurality of layers.

30. The heat dissipating assembly using a heat dissipating substrate of claim 26, wherein said base is a stairway shaped base.

31. A heat dissipating assembly using a heat dissipating substrate, comprising a heat dissipating substrate and a base, and said heat dissipating substrate and said base respectively comprise a cavity and a hole groove.

32. The heat dissipating assembly using a heat dissipating substrate of claim 31 wherein said cavity for receiving a metal pillar is riveted with a hole groove disposed on said base.

33. The heat dissipating assembly using a heat dissipating substrate of claims 8, 13, 14, 18, 23, 26, or 31, wherein said base is made of a copper alloy.

34. The heat dissipating assembly using a heat dissipating substrate of claims 8, 13, 14, 18, 23, 26, or 31, wherein said base is made of an aluminum alloy.

35. The heat dissipating assembly using a heat dissipating substrate of claims 8, 13, 14, 18, 23, 26, or 31, wherein said base is made of a graphite compound material.
